(19) United States
(12) Patent Application Publication
(10) Pub. No.: US 2010/0055828 A1
(43) Pub. Date: Mar. 4, 2010

(54) PROCESS AND PASTE FOR CONTACTING METAL SURFACES

(75) Inventors: Wolfgang SCHMITT, Rodgau (DE); Tanja DICKEL, Neuberg (DE); Katja STENGER, Wiesen (DE)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: W.C. HERAEUS GMBH, Hanau (DE)

(21) Appl. No.: 12/615,516

(22) Filed: Nov. 10, 2009

Related U.S. Application Data
(62) Division of application No. 12/237,660, filed on Sep. 25, 2008.

(30) Foreign Application Priority Data
Sep. 28, 2007 (DE) 102007046901.4
Jul. 8, 2008 (DE) 102008031893.0

(51) Int. Cl. H01L 31/18; B05D 5/12; H01L 21/441

(52) U.S. Cl. 438/98; 427/126.1; 438/686; 257/E31.001; 257/E21.477

(57) ABSTRACT

For production of an electrically conductive or thermally conductive connection for contacting two elements, an elemental metal, in particular silver, is formed from a metal compound, in particular a silver compound, between the contact surfaces. In this production, the processing temperature for the use of a silver solder can be decreased below 240° C. and the processing pressure can be reduced to normal pressure. A contacting paste for this purpose contains a metal compound, in particular a silver compound, which decomposes below 400° C. while forming elemental silver. As a result, a metal is generated in situ from a chemical compound for producing a contact, which is usable above the temperature necessary for its production.

### CROSS-REFERENCE TO RELATED APPLICATIONS

This application is a divisional of pending U.S. patent application Ser. No. 12/237,660, filed Sep. 25, 2008, the disclosure of which is incorporated herein by reference.

### BACKGROUND OF THE INVENTION

The present invention relates to contacting pastes, in particular silver pastes, for fastening loose components arranged in a sandwich-like configuration relative to each other.

For the sandwich construction of electronic components to be joined to each other, contacting pastes are sintered from silver flakes dispersed in a solvent under pressure on the order of magnitude of 30 MPa at temperatures of approximately 300° C., in order to deposit a thin film of approximately 50 μm on an electronic component (chip). In this way, a reliable connection of the chip and substrate is created, which withstands operating temperatures of greater than 250° C. The surfaces to be connected must be a precious metal, in particular made of silver or gold.

International patent application publication WO 2004/026526 discloses the application of nanosilver with particle sizes <100 nm, in order to reduce the pressure to approximately 20 MPa and the temperature to approximately 250° C.

According to U.S. Pat. No. 6,951,666, easily decomposable silver compounds are used in pastes for creating screen prints, for example, together with silver flakes or nanosilver or a combination of silver flakes and nanosilver.

### BRIEF SUMMARY OF THE INVENTION

The object of the present invention lies in providing, on the one hand, contacts that have a melting point as much as possible above that of a solder, but on the other hand, that can be produced as easily as with solder. Electronic components having a temperature application range that extends above 200° C., and possibly even above 250° C., are fastened more easily on substrates. Therefore, in particular, the pressure load should be reduced. In this way, a suitable contacting paste should be provided.

For achieving the object, loose components are fastened on each other over their full surfaces by contact paste far below the melting point of the metal with which the fastening is performed.

For the production of an electrically conductive or a heat-conductive connection for stable contacting of two loose elements according to the invention, in particular an electronic component with another component, a metal compound, in particular a silver compound, is converted into elemental metal, in particular silver, between the contact surfaces. For this purpose, non-precious metallization surfaces, e.g., copper metallization surfaces, on the components are sufficient to produce a fixed contact between the components.

With the joining of two electronic components to be sandwiched together by an electrically conductive or a heat-conductive compound for contacting the components, the decomposition of a metal compound, in particular silver compound, into an elemental metal, in particular silver, between the contact surfaces of the components allows a considerable reduction of pressure and temperature, in order to sinter the components to each other. The sandwich-like joining is realized, for the sake of simplicity, in an oven or by a heating plate, in particular in a circulating-air drying chamber or a continuous oven with heating plate systems or by a heatable die.

A decisive feature for the present invention is that the sandwich-like contacting of the components is their mechanical fastening to each other, which is preferably also used for heat conduction or electrical connection.

Preferably,
the metal compound is a silver compound, such as silver carbonate or silver oxide, or an organic metal compound, in particular an organic silver compound;
a contact surface has non-precious metal in the surface;
the process temperature for producing the silver contact lies below 400° C., in particular between 150° and 350° C.;
the production of the silver contact is performed under atmospheric pressure;
a paste containing the silver compound is deposited on a contact surface;
the metal contact is a uniform layer.

The paste preferably contains a gel, according to German published patent application DE 10 2005 053 553 A1, and copper or silver particles, in particular in a range between 0.2 μm and especially preferred between 0.5 μm and 2 μm.

Metal compounds, in particular silver compounds, that decompose below 300° C., in particular below 250° C., and in this way form elemental metal, in particular silver, are especially suitable for considerably improving sinter pastes with respect to their application between 200° to 300° C. According to the invention, contacting pastes are provided that have easily decomposable silver compounds. These pastes according to the invention allow contacting at a lower contact pressure, in particular below 5 bar, preferably below 3 bar, and at a processing temperature of approximately 230° C., i.e., below 250° C., in particular below 240° C.

The contacting between the surfaces according to the invention is stable with temperature changes above 200° C., and indeed above 2000 cycles. Thus, the contacting paste exceeds the temperature stability and temperature change stability that can be achieved with solder alloys or conductive adhesives. Within the scope of the present invention it is thus possible that the contacting temperature of the contacting paste lies below the operating temperature of the contacts produced with the paste. This simplifies the method for producing sandwich-like modules made of electronic components. The easily decomposable silver compounds according to the invention can be produced more easily and are easier to conserve than nanosilver. During storage nanosilver loses the desired properties, because the surface decreases in size continuously due to agglomeration and is thus no longer suitable for joining.

A decisive factor is that the paste has, in addition to its organic components, such as solvent and/or carboxylic acids, an easily decomposable metal compound, in particular silver compound, by which a processing below 400° C., such as with solder, is made possible. Preferably, the silver compound forms metallic silver below 300° C., in particular below 250° C. Suitable silver compounds are silver oxide, silver carbonate, and particularly organic silver compounds. Silver lactate has proven especially effective.

It is presumed that the pastes and methods according to the invention involve the formation of highly reactive metal generated in situ, in particular silver, which connects the contact surfaces and the solids optionally present in the paste to each other. Here, it appears possible that the metal produced from the decomposed metal compound first forms a reactive grain surface on the solids, which is later easily sintered, or that the metal produced from the metal compound immediately connects the grain boundaries to each other. In this respect, for the connection mechanism according to the present invention, it is not clear whether it mainly involves sintering, bonding, or compaction. In any case, the mechanical strength of the joint is increased by the decomposition of the metal compound and its porosity is reduced, in particular by 1 to 20%.

Easily decomposable silver compounds are usable in known pastes, for example together with silver flakes or nanosilver or a combination of silver flakes and nanosilver. In another preferred embodiment, a paste is provided with an easily decomposable silver compound and copper powder. The particle size of the copper powder preferably equals less than 10 μm.

Typical contact surfaces of the components are metallization surfaces made of precious metal or having a precious metal coating. The paste according to the invention is further suitable for connecting non-precious metal surfaces, for example copper surfaces.

According to the invention, in addition to silver surfaces, a fixed connection with very good electrical conductivity, even at approximately 230° C., is also sintered on copper and nickel-gold surfaces. The tensile load of the connections equals approximately 50 MPa.

The pastes according to the invention are suitable for the attachment of cooling bodies or LEDs as well as for use in optoelectronics and power electronics (power modules), in particular DCB (Direct Copper Bonding) and Die Attach.

Preferably, the contacting paste is resin-free. In particular, a gel according to DE 10 2005 053 553 A1 is mixed with an easily decomposable silver compound and optionally also with a metal powder, such as silver flakes, nanosilver, or copper powder.

According to the invention, a low-temperature sinter technology (NTV) is created, which will push back bonding wire technology, since two-sided heating of components with the sinter paste according to the invention is advantageous.

According to the invention, it is possible to apply the paste by dispensing, and in particular template printing, or by a spraying method, instead of by screen printing.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a schematic, side sectional view showing the full-surface fastening of LEDs on a cooling body, according to an embodiment of the invention;

FIG. 2 is a schematic, side sectional view showing the full-surface fastening of an electronic component (chip) on a conductor track, according to another embodiment of the invention;

FIG. 3 is a schematic, side sectional view showing the full-surface fastening of a DCB on a cooling body, according to a further embodiment of the invention;

FIG. 4 is a schematic, side sectional view showing the fastening of an Si semiconductor on a Cu substrate, according to an embodiment of the invention;

FIG. 5 is a pair of schematic, side sectional views showing the electrical, thermal, and mechanical connection of a semiconductor (e.g., Si or GaAs) with another semiconductor, e.g. (Si or GaAs) (=Stacked Die), according to another embodiment of the invention;

FIG. 6 is a schematic, side sectional view showing the electrical, thermal, and mechanical connection of a semiconductor on a metallization surface (flip chip), according to another embodiment of the invention;

FIG. 7 is a schematic, side sectional view showing the electrical, thermal, and mechanical connection of an electronic component with another electronic component, wherein one component is fixed on the other component (Package on Package/PoP), according to a further embodiment of the invention; and

FIG. 8 is a schematic, side sectional view showing the electrical, thermal, and mechanical connection of a solar cell on a substrate or cooling body made of metal, ceramic, or plastic, according to an embodiment of the invention.

### DETAILED DESCRIPTION OF THE INVENTION

The contacting is realized between the metallization surfaces provided on the components for this purpose. These metallization surfaces defining the metal contact are not shown in the Figures, because, in the case of a silver contact between silver metallization surfaces or copper contact between copper metallization surfaces, they disappear into the contact.

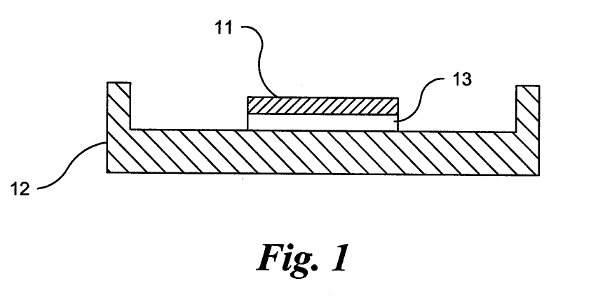

According to an embodiment from FIG. 1, an LED 11 is fastened on a cooling body 12 with contact 13.

The heat caused by the LED 11 raises the risk of brittleness for solder contacts due to the formation of intermetallic phases and thus negatively affects the reliability of the contacts.

With a contacting paste according to the invention made of a gel according to DE 10 2005 053 553 A1, in which silver lactate is dispersed together with silver flakes, a pure silver contact is produced that naturally has the best thermal conductivity and exhibits no aging under the continuous temperature load of the LED.

For the production of an LED mount according to FIG. 1, a paste made of 80 wt. % silver, 5 wt. % silver lactate, and 15 wt. % gel according to DE 10 2005 053 553 A1 is deposited on the entire surface area on the unconnected cooling body 12. Then, the unconnected LED 11 is set on the paste and the blank is heated in the oven to 230° C. for 45 to 60 minutes. The silver contact 13 generated in this way is the best possible thermal conductor with unrestricted reliability for LED use. The contact 13 is stable at far higher temperatures.

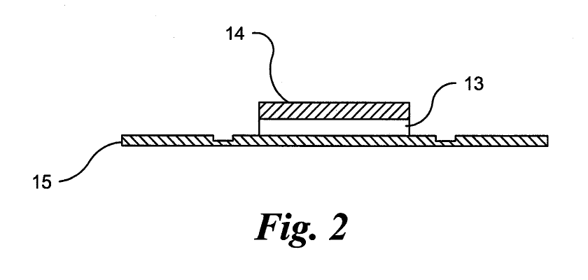

According to one embodiment from FIG. 2, a high-temperature sensor 14 according to

European patent application publication EP 0 809 094 A1 of Heraeus Sensor Technology GmbH is fastened on a conductor frame 15 with a contact 13. The high-temperature application of the high-temperature sensor 14, whose application range reaches over 500° C., would be limited for solder contacts to the melting temperature of the solder, whereby the brittleness would limit the period of use of the contacts due to the formation of intermetallic phases.

With a contacting paste according to the present invention, made of a gel according to DE 10 2005 053 553 A1 in which silver carbonate is dispersed together with silver flakes, a pure silver contact is produced that naturally exhibits the best electrical conductivity and is absolutely reliable at the applied temperatures of the sensor.

For production of a chip contacting according to FIG. 2, a paste made of 80 wt. % silver, 5 wt. % silver carbonate, and 15 wt. % gel according to DE 10 2005 053 553 A1 is deposited on the conductor frame 15. Then, the chip 14 is set on the paste and the blank is heated in an oven to 260 to 270° C. for 30 to 60 minutes. The silver contact 13 generated in this way is the best possible electrical conductor with the desired reliability for the sensor application.

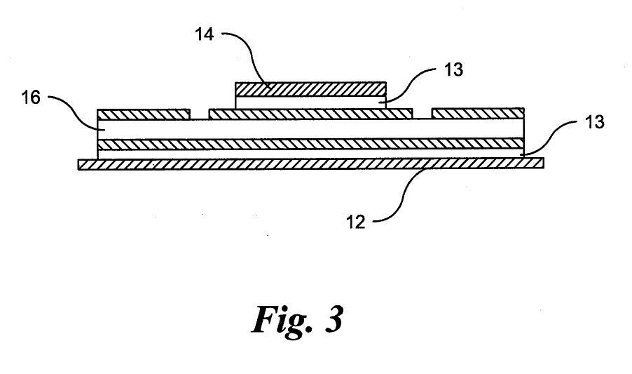

According to an embodiment from FIG. 3, a DCB 16 is fastened to a chip 14 in an electrically conductive way and fastened to a cooling body 12 in a thermally conductive way, each with a contact 13. The heat generation of the chip 14 raises the risk of brittleness with solder contacts due to the formation of intermetallic phases and thus negatively affects the reliability of the contacts 13.

With a contacting paste according to the invention made of a gel according to DE 10 2005 053 553 A1, in which silver lactate is dispersed in addition to silver flakes and copper flakes, for the contacting of the DCB with the cooling body, a pure metal contact is created that features very good thermal conductivity and exhibits no aging below the continuous temperature load of the chip.

With a contacting paste according to the invention made of a gel according to DE 10 2005 053 553 A1, in which silver lactate is dispersed together with silver flakes, for the contacting of the DCB with the chip, a pure metal contact is created that features very good electrical conductivity and exhibits no aging under the continuous temperature load of the chip.

For production of DCB contacts according to FIG. 3, a paste made of 60 wt. % copper, 20 wt. % silver, 5 wt. % silver lactate, and 15 wt. % gel according to DE 10 2005 053 553 A1 is deposited on the cooling body 12. Then, the DCB 16 is set on the paste and coated with a paste made of 80 wt. % silver, 5 wt. % silver lactate, and 15 wt. % gel according to DE 10 2005 053 553 A1, whereupon the chip 14 is set on this paste and this blank is heated in an oven to 240° C. at an isostatic pressure of 2 to 3 bar for 20 to 40 minutes. The silver contact 13 generated in this way is the best possible electrical conductor with unrestricted reliability for the chip application. The copper-silver contact 13 is reliable for very good heat transfer.

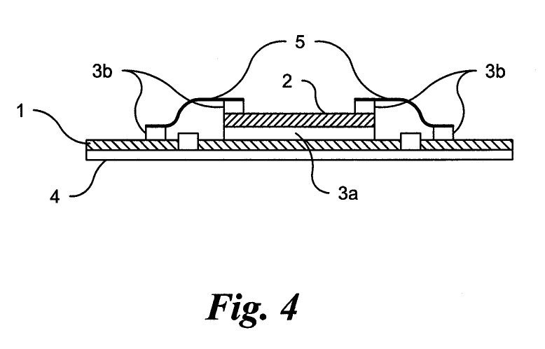

FIG. 4 shows the fastening of an LED or Si semiconductor 2 on a conductor track 1 with a silver layer 3a produced according to the invention. The chip 2 is connected electrically via strips 5 to the track 1, which are likewise attached with silver layers 3b. Conductor tracks and strips made of copper or silver have proven effective, in particular conductor tracks fixed on an electrically insulating carrier substrate.

With a contacting paste according to the invention made of a gel according to DE 10 2005 053 553 A1, in which silver lactate is dispersed together with silver flakes, a pure silver contact 3 is created, which naturally features the best thermal conductivity and exhibits no aging under the continuous temperature load of the chip 2 or LED.

For production of the silver contact, circulating air drying chambers or continuous ovens with heating plate systems or dies (such as a flip-chip bonder or die bonder) have each proven effective using a controllable temperature profile under the following conditions:

Temperature profile during contacting:

Heating rate ≧0.5° K/s;

Final temperature 230-400° C.;

Processing time from heating until cooling 5-60 min

Oven atmosphere: air or nitrogen (residual oxygen content >1000 ppm) or forming gas (residual oxygen content >1000 ppm) or vacuum >10 mbar (residual oxygen content >100 ppm)

At a heating rate below 0.3° K/s or a final temperature below 200° C. or a heat treatment less than 5 minutes or a vacuum below 10 mbar, no usable solidification takes place, so that no load-bearing silver layer is obtained.

The level of the final temperature is determined by the temperature sensitivity of the components. Air atmosphere is the preferred sinter atmosphere. Nitrogen or forming gas is used to protect the Cu substrate surface from oxidation. A vacuum, in particular between 100 and 300 mbar, prevents additional air inclusions.

For production of an Si chip mount according to FIG. 4, a paste made of 80 wt. % silver, 5 wt. % silver lactate, and 15 wt. % gel according to DE 10 2005 053 553 A1 is deposited on a structured 2 mm thick and 10 mm wide Cu substrate 1. Then, the chip is set on the paste and the blank is heated in an oven to 230° C. for 45 to 60 minutes. The silver contact 3a generated in this way is the best possible heat conductor with unlimited reliability for the chip application. The contact 3a is stable at far higher temperatures than 230° C.

With a contacting paste according to the invention made of a gel according to DE 10 2005 053 553 A1, in which silver lactate is dispersed together with silver flakes and copper flakes, a pure metal contact is created, which features very good thermal conductivity and exhibits no aging under the continuous temperature load of the power module, for contacting of the chip with the DCB. This contact is better suited as a pure silver contact, particularly due to the high current densities in DCB applications.

Analogous to the example according to FIG. 4, with a contacting paste according to the invention made of a gel according to DE 10 2005 053 553 A1, in which silver carbonate is dispersed together with silver flakes, a pure silver contact is produced for the examples according to FIGS. 2, 3, 4, and 5, which naturally also features the best electrical conductivity and is absolutely reliable for the applied temperatures of the sensor.

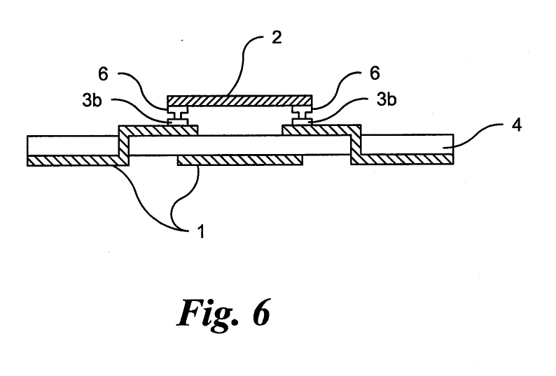

Analogous to FIG. 4, for production of a chip contacting according to FIGS. 6 to 8, a paste made of 80 wt. % silver, 5 wt. % silver carbonate, and 15 wt. % gel according to DE 10 2005 053 553 A1 is deposited on the conductor frame 1, which is optionally fixed on an electrically insulating substrate 4. Then, the chip 2 is set on the paste and the blank is heated to 260° C. to 270° C. in an oven for 30 to 60 minutes. The silver contact 3 generated in this way is the best possible electrical conductor with the desired reliability for the sensor application.

With a contacting paste according to the invention made of a gel according to DE 10 2005 053 553 A1, in which silver lactate is dispersed together with silver flakes, a pure metal contact is produced, which features very good electrical conductivity and exhibits no aging under the continuous temperature load of the chip, for the contacting of the silver strip with the chip.

Analogous to FIG. 4, the silver contacts 3 in FIGS. 6 to 8 are designated with 3a for full-surface heat transfer contacts and with 3b for electrical contacts.

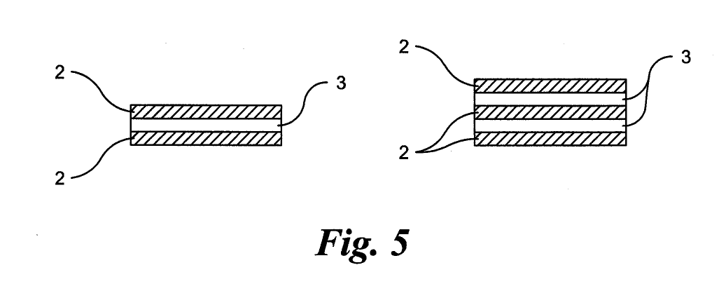

FIG. 5 shows the electrical, thermal, and mechanical connection of a semiconductor, e.g., Si or GaAs, to another semiconductor, e.g., Si or GaAs (=stacked die). This schematic is valid both for semiconductors, whose front sides are connected to each other or wherein the rear side of one component (back end) is connected to the top side of the other component (front end).

According to FIG. 6, the front sides of the semiconductor 2 are fixed by bumps 6 made of Cu, Ag, or Au to a silver contact 3b on a metallization surface, wherein the metallization surface is connected electrically to the copper track 1 (flip chip).

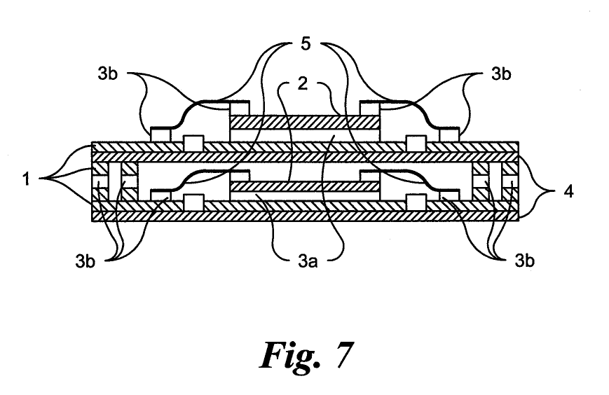

In FIG. 7, the electrical, thermal, and mechanical connection 3 of an electronic component according to FIG. 1 is represented with another electronic component according to FIG. 1, wherein the one component is fastened on the other component (Package on Package/PoP). The components are no longer connected to each other according to the invention after the production of the individual components, but instead during the production of the silver contacts 3 of the components, the silver contacts 3 are also already produced for the fastening of the components on each other.

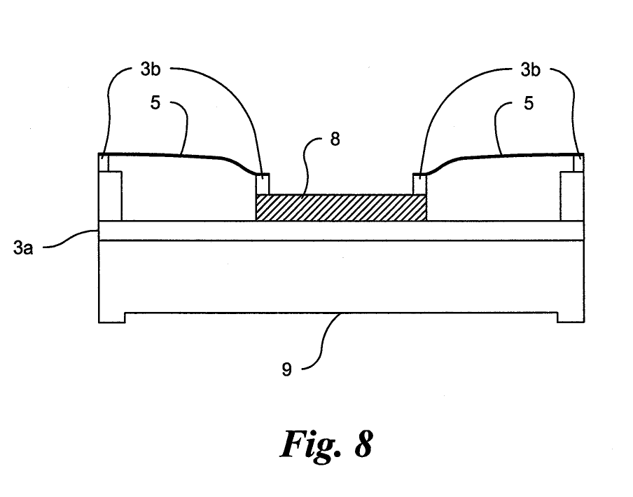

In FIG. 8 the electrical, thermal, and mechanical connection 3a of a solar cell 8 on a substrate or cooling body 9 made of metal, ceramic, or plastic is represented. The cooling of the solar cell 8 is considerable for its power and service life, because the operating temperature of a solar cell 8 can lie far above the production temperature of the silver contact 3a, with which the solar cell 8 is fastened on the cooling body 9.

In particular for solar cells a reliable electrical, thermal, and mechanical connection 3 of an electrical component with other components of the same functionality or other electrical or electronic functionality is required. The solar cells 8 arranged in series are connected electrically via silver contacts 3b and silver or copper strips to metal contacts, in order to discharge the electrical current generated in the solar cells 8.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A process for producing an electrically conductive or thermally conductive connection for contacting two elements, comprising forming elemental silver in situ from a silver compound between contact surfaces of the two elements standing one over another.

2. The process according to claim 1, wherein the silver compound is selected from an organic silver compound or silver carbonate.

3. The process according to claim 1, wherein at least one of the contact surfaces has a non-precious metal in its surface.

4. The process according to claim 1, wherein the contacting process is carried out at a temperature below 400° C.

5. The process according claim 1, wherein the silver compound is present in a paste, which is deposited on one of the contact surfaces.

6. The process according to claim 1, wherein the contacting of the two elements comprises fastening:
a) of cooling bodies or LEDs or DCBs or solar cells; or
b) Si semiconductors on a Cu substrate; or
c) for a flip chip or Package on Package (PoP).

7. A process for producing a full-surface metal contact between a metallic connection surface of an electronic component and a metallic connection surface of another component for fixing the components to each other at a temperature below 400° C., the process comprising applying to a contact surface of one of the components a material comprising a compound of metal or a component thereof, wherein the material decomposes below 400° C. into the metal or a component thereof, and wherein the metal or component thereof is one that melts just above 400° C., such that the metal contact is produced in situ by decomposition of the material below 400° C.

8. The process according to claim 7, wherein the process comprises forming elemental silver in situ from a silver compound between contact surfaces of one of the electrical components and the other component standing over one another.

9. The process according to claim 7, wherein at least one of the contact surfaces has a non-precious metal in its surface.

10. The process according to claim 7, wherein the contacting process is carried out at a temperature below 400° C.

11. The process according to claim 7, wherein the silver compound is present in a paste, which is deposited on one of the contact surfaces.

12. The process according to claim 7, wherein the contacting of the two components comprises fastening:
(a) of cooling bodies or LEDs or DCBs or solar cells; or
(b) Si semiconductors on a Cu substrate; or
(c) for a flip chip or Package on Package (PoP).

13. The process according to claim 7, wherein the material comprises a paste
containing a solid in an organic mass, wherein the organic mass is a gel and the solid comprises a silver compound which decomposes below 400° C. with formation of elemental silver, and wherein the contacting paste contains silver or copper particles.

14. The process according to claim 7, wherein the contacted surfaces form an electrically conducting or thermally conducting connection, and wherein the process takes place at pressures up to 5 bar or at a processing temperature below 240° C. or at pressures up to 5 bar and a processing temperature below 240° C.

15. A process for connecting surfaces of electronic components using a contacting paste containing a solid in an organic mass, wherein the organic mass is a gel and the solid comprises a silver compound which decomposes below 400° C. with formation of elemental silver, and wherein at least one of the surfaces to be connected is made of a non-precious metal.

16. The process according to claim 15, wherein the contacted surfaces form an electrically conducting or thermally conducting connection, and wherein the process takes place at pressures up to 5 bar or at a processing temperature below 240° C. or at pressures up to 5 bar and a processing temperature below 240° C.

17. The process according to claim 15, wherein the process comprises low-pressure contacting in a field of power electronics or opto-electronics or for fastening LEDs or cooling bodies.

18. The process according to claim 15, wherein the paste comprises a mixture of copper powder and a metal compound decomposable below 400° C.

19. The process according to claim 15, wherein the surfaces comprise metallic surfaces of two respective objects, and wherein the process comprises forming a metal contact by generating metal from a chemical compound below a maximum use temperature of the contact generated.

20. The process according to claim 15, wherein the electronic components loose electrical components, and wherein the method provides for full-surface fastening of the loose components.
